(19) United States
(12) Patent Application Publication
(10) Pub. No.: US 2026/0353951 A1
(43) Pub. Date: Nov. 5, 2026

(54) Display Device And Electronic Device Including The Same

(71) Applicant: Samsung Display Co., Ltd., Yongin-si (KR)

(72) Inventors: KYUNG-BAE KIM, Yongin-si (KR); DONGWOO KIM, Yongin-si (KR); YEONKYUNG KIM, Yongin-si (KR); YONGHEE LEE, Yongin-si (KR)

(73) Assignee: Samsung Display Co., Ltd., Yongin-si (KR)

(21) Appl. No.: 19/653,311

(22) Filed: Apr. 21, 2026

(30) Foreign Application Priority Data
Apr. 30, 2025 (KR) 10-2025-0057538

(51) Int. Cl. H10K 59/131; H10K 59/121

(52) U.S. Cl. CPC H10K 59/131; H10K 59/1213

(57) ABSTRACT

A display device includes an active pattern including a source region, a drain region, and a channel region, a gate electrode overlapping the channel region, a first-first electrode line on the gate electrode and connected to the gate electrode, a first-second electrode line in the same layer as the first-first electrode line, connected to the source region of the active pattern, and spaced apart from the first-first electrode line, a first data line on the first-first electrode line, a second-first electrode line in the same layer as the first data line, at least partially overlapping the first-second electrode line, and connected to the first-first electrode line, and a second-second electrode line in the same layer as the first data line, at least partially overlapping the first-first electrode line, connected to the first-second electrode line, and closer to the first data line than the second-first electrode line.

### CROSS-REFERENCE TO RELATED APPLICATION

This application claims priority under 35 U.S.C. §119 to Korean Patent Application No. 10-2025-0057538 filed on Apr. 30, 2025, the entire contents of which are hereby incorporated by reference.

### TECHNICAL FIELD

Aspects of the present disclosure relate to a display device and an electronic device including the same. More particularly, aspects relate to a display device for providing visual information and an electronic device including the same.

### BACKGROUND

A display device may include a display region for displaying an image. The display device is a device that displays the image to provide visual information to users. An organic light emitting diode (OLED) display and a micro OLED display have recently attracted attention.

As a degree of integration of the display device is increased, a coupling between data lines and electrode lines included in the display device may occur. When the coupling occurs in the display device, a display quality of the display device may be reduced. Various studies are being conducted to solve this problem.

### SUMMARY

Aspects of the present disclosure are directed to a display device with improved reliability.

Aspects of the present disclosure are also directed to an electronic device including the display device.

Additional features of the aspects of the present disclosure will be set forth in the description which follows, and in part will be apparent from the description, or may be learned by practice of the concepts described herein.

A display device according to an aspect includes an active pattern disposed on a substrate and including a source region, a drain region, and a channel region, a gate electrode disposed on the active pattern and overlapping the channel region of the active pattern, a first-first electrode line disposed on the gate electrode and electrically connected to the gate electrode, a first-second electrode line disposed in the same layer as the first-first electrode line, electrically connected to the source region of the active pattern, and spaced apart from the first-first electrode line in a plan view, a first data line disposed on the first-first electrode line and configured to apply a data voltage, a second-first electrode line disposed in the same layer as the first data line, at least partially overlapping the first-second electrode line in the plan view, and electrically connected to the first-first electrode line, and a second-second electrode line disposed in the same layer as the first data line, at least partially overlapping the first-first electrode line in the plan view, electrically connected to the first-second electrode line, and disposed closer to the first data line than the second-first electrode line.

In an aspect, the first-first electrode line may include a first-first body portion extending in the first direction and first-first branch portions each extending in a second direction crossing the first direction from the first-first body portion. The first-second electrode line may include a first-second body portion extending in the first direction and first-second branch portions each extending in the second direction from the first-second body portion. The second-first electrode line may include a second-first body portion extending in the first direction and second-first branch portions each extending in the second direction from the second-first body portion. The second-second electrode line may include a second-second body portion extending in the first direction and second-second branch portions each extending in the second direction from the second-second body portion.

In an aspect, the first-first branch portions may at least partially overlap the second-second branch portions in the plan view. The first-second branch portions may at least partially overlap the second-first branch portions in the plan view.

In an aspect, a number of the first-second branch portions of the first-second electrode line may be greater than a number of the first-first branch portions of the first-first electrode line. A number of the second-second branch portions of the second-second electrode line may be greater than a number of the second-first branch portions of the second-first electrode line.

In an aspect, a number of the second-first branch portions may be greater than a number of the first-first branch portions.

In an aspect, the first data line and the second-second electrode line may be spaced apart from each other by a first spacing distance in the plan view. The first spacing distance may be in a range of about 0.1 micrometers to about 0.2 micrometers.

In an aspect, the display device may further include a second data line disposed on the first data line and electrically connected to the first data line.

In an aspect, the display device may further include a third-first electrode line disposed in the same layer as the second data line, at least partially overlapping the first-first electrode line in the plan view, and electrically connected to the first-first electrode line, and a third-second electrode line disposed in the same layer as the third-first electrode line, at least partially overlapping the first-second electrode line in the plan view, and electrically connected to the first-second electrode line.

In an aspect, the second data line and the third-second electrode line may be spaced apart from each other by a second spacing distance in the plan view. The second spacing distance may be in a range of about 0.25 micrometers to about 0.6 micrometers.

In an aspect, the display device may further include power electrode lines disposed on the third-first electrode line and to which a power voltage is applied.

In an aspect, in a plan view, a width of each of the power electrode lines may be in a range of about 6000 angstroms to about 15000 angstroms.

In an aspect, a number of the first-second branch portions of the first-second electrode line may be greater than a number of the first-first branch portions of the first-first electrode line. A number of the second-second branch portions of the second-second electrode line may be greater than a number of the second-first branch portions of the second-first electrode line.

In an aspect, the display device may further include a third-first electrode line disposed in the same layer as the second data line, at least partially overlapping the first-first electrode line in the plan view, and electrically connected to the first-first electrode line, and a third-second electrode line disposed in the same layer as the third-first electrode line, at least partially overlapping the first-second electrode line in the plan view, and electrically connected to the first-second electrode line.

In an aspect, the display device may further include a first connection electrode disposed between the gate electrode and the first-first electrode line in a cross-sectional view. The first connection electrode may be electrically connected to the gate electrode and the first-first electrode line.

In an aspect, the display device may further include a second connection electrode disposed between the active pattern and the first-second electrode line in a cross-sectional view. The second connection electrode may be electrically connected to the active pattern and the first-second electrode line.

In an aspect, in a plan view, a width of each of the first-first electrode line and the first-second electrode line may be in a range of about 0.1 micrometers to about 0.25 micrometers.

In an aspect, the display device may further include a first-third electrode line disposed in the same layer as the first-first electrode line, spaced apart from the first-first electrode line in the plan view, and to which a reference voltage is applied.

In an aspect, the display device may further include an interlayer insulating layer disposed between the first-first electrode line and the second-first electrode line. The interlayer insulating layer may include an oxide.

An electronic device according to an aspect includes a display device and a processor configured to drive the display device. The display device includes an active pattern disposed on a substrate and including a source region, a drain region, and a channel region, a gate electrode disposed on the active pattern and overlapping the channel region of the active pattern, a first-first electrode line disposed on the gate electrode and electrically connected to the gate electrode, a first-second electrode line disposed in the same layer as the first-first electrode line, electrically connected to the source region of the active pattern, and spaced apart from the first-first electrode line in a plan view, a first data line disposed on the first-first electrode line and configured to apply a data voltage, a second-first electrode line disposed in the same layer as the first data line, at least partially overlapping the first-second electrode line in the plan view, and electrically connected to the first-first electrode line, and a second-second electrode line disposed in the same layer as the first data line, at least partially overlapping the first-first electrode line in the plan view, electrically connected to the first-second electrode line, and disposed closer to the first data line than the second-first electrode line.

In an aspect, the first-first electrode line may include a first-first body portion extending in the first direction and first-first branch portions each extending in a second direction crossing the first direction from the first-first body portion. The first-second electrode line may include a first-second body portion extending in the first direction and first-second branch portions each extending in the second direction from the first-second body portion. The second-first electrode line may include a second-first body portion extending in the first direction and second-first branch portions each extending in the second direction from the second-first body portion. The second-second electrode line may include a second-second body portion extending in the first direction and second-second branch portions each extending in the second direction from the second-second body portion.

The display device according to aspects of the present disclosure may include the active pattern disposed on the substrate and including the source region, the drain region, and the channel region, the gate electrode disposed on the active pattern and overlapping the channel region of the active pattern, the first-first electrode line disposed on the gate electrode and electrically connected to the gate electrode, the first-second electrode line disposed in the same layer as the first-first electrode line, electrically connected to the source region of the active pattern, and spaced apart from the first-first electrode line in the plan view, the first data line disposed on the first-first electrode line and configured to apply the data voltage, the second-first electrode line disposed in the same layer as the first data line, at least partially overlapping the first-second electrode line in the plan view, and electrically connected to the first-first electrode line, and the second-second electrode line disposed in the same layer as the first data line, at least partially overlapping the first-first electrode line in the plan view, electrically connected to the first-second electrode line, and disposed closer to the first data line than the second-first electrode line.

Accordingly, by disposing the electrode lines, to which different voltages are applied, to overlap each other in a plan view, the capacitor may also be formed in vertical direction. Therefore, compared to a case in which electrode lines, to which the same voltage is applied, are disposed to overlap each other in a plan view, a total capacitance of the capacitor in the display device DD may increase.

In addition, since the electrode line electrically connected to the source region is disposed closer to the first data line, the coupling may be prevented or reduced. Therefore, the reliability of the display device may be improved, and high-resolution images may be stable implemented due to the increased capacitance of the capacitor.

It is to be understood that both the foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the present disclosure and are incorporated in and constitute a part of this specification, illustrate aspects of the present disclosure, and together with the description serve to explain technical features of the present disclosure.

FIG. 1 is a perspective view illustrating a display device according to an aspect.

FIG. 2 is a block diagram illustrating components of the display device of FIG. 1.

FIG. 3 is an equivalent circuit diagram illustrating an aspect of a pixel of FIG. 2.

FIG. 4 is a cross-sectional view illustrating an aspect of a display panel of FIG. 2.

FIG. 5 is a cross-sectional view illustrating an aspect of an electrode line layer of FIG. 4.

FIG. 6 is a plan view illustrating an aspect of a first electrode line layer of FIG. 5.

FIG. 7 is a plan view illustrating an aspect of a second electrode line layer and a first data line of FIG. 5.

FIG. 8 is a plan view illustrating an aspect of a third electrode line layer and a second data line of FIG. 5.

FIG. 9 is a plan view illustrating an aspect of a fourth electrode line layer of FIG. 5.

FIG. 10 is a cross-sectional view illustrating an aspect of an electrode line layer of FIG. 4.

FIG. 11 is a block diagram illustrating an electronic device according to an aspect.

FIG. 12 is a schematic diagram illustrating electronic devices according to various aspects.

### DETAILED DESCRIPTION

Various aspects will be described more fully hereinafter with reference to the accompanying drawings, in which some aspects of the present disclosure are shown. The present disclosure may, however, take many different forms and should not be construed as limited to the aspects set forth herein. Rather, aspects set forth herein are provided so that this disclosure will be thorough and complete, and will fully convey the scope of the aspects of the present disclosure to those skilled in the art. In the drawings, the sizes and relative sizes of layers and regions may be exaggerated for clarity.

In the disclosure, various modifications can be made, various forms can be used, and specific aspects will be illustrated in the drawings and described in detail in the text. However, this is not intended to limit the disclosure to a specific form disclosed, and it will be understood that all changes, equivalents, or substitutes which fall in the spirit and technical scope of the disclosure should be included.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present disclosure. As used herein, the term “and/or” includes any and all combinations of one or more of the associated listed items.

It will be understood that when an element is referred to as being “connected” or “coupled” to another element, it can be directly connected or coupled to the other element or intervening element(s) may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular aspects only and is not intended to be limiting of the present disclosure. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, aspects of the present disclosure will be described in detail with reference to the accompanying drawings. The same reference numerals are used for the same components in the drawings, and redundant descriptions of the same components will be omitted.

In the present specification, a plane may be defined by a first direction D1 and a second direction D2 crossing the first direction D1. For example, the second direction D2 may be perpendicular to the first direction D1. In addition, a third direction D3 may be a normal direction of the plane. That is, the third direction D3 may be perpendicular to the plane defined by the first direction D1 and the second direction D2.

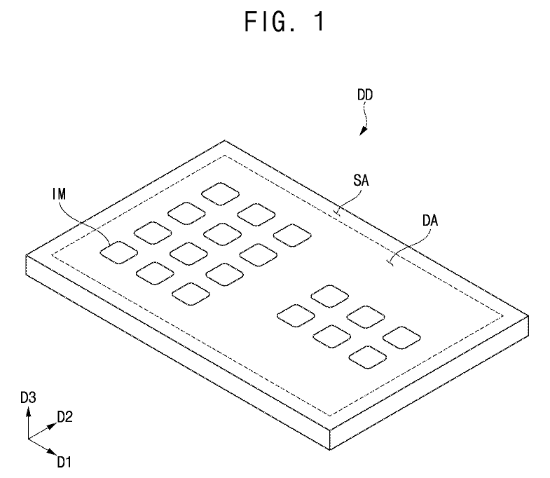

FIG. 1 is a perspective view illustrating a display device according to an aspect of the present disclosure.

Referring to FIG. 1, the display device DD may include a display region DA and a peripheral region SA. The display region DA may be at least partially surrounded by the peripheral region SA.

The display region DA may be a region that displays an image by generating light or controlling a transmittance of light provided from an external light source. The peripheral region SA may be a region that does not display an image. However, aspects of the present disclosure are not limited thereto, and at least a portion of the peripheral region SA may display an image.

The display region DA may display one or more images IM. Users may receive information from the display device DD through the images IM.

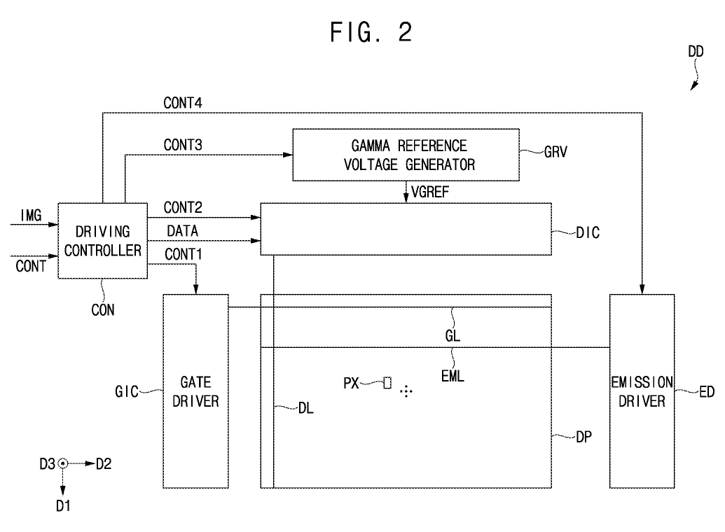

FIG. 2 is a block diagram illustrating components of the display device of FIG. 1.

Referring to FIGS. 1 and 2, the display device DD may include a display panel DP and a display panel driver. The display panel driver may include a driving controller CON, a gate driver GIC, a gamma reference voltage generator GRV, a data driver DIC, and an emission driver ED.

The display panel DP may include the display region DA that displays an image and the peripheral region SA disposed to be adjacent to the display region DA.

The display panel DP may include gate lines GL, data lines DL, emission control lines EML, and pixels PX electrically connected to the gate lines GL, the data lines DL, and the emission control lines EML.

The gate lines GL may each extend from the gate driver GIC in the second direction D2, and may be spaced apart from each other in the first direction D1. The data lines DL may each extend from the data driver DIC in the first direction D,1 and may be spaced apart from each other in the second direction D2. The emission control lines EML may each extend from the emission driver ED in a direction opposite to the second direction D2, and may be spaced apart from each other in the first direction D1.

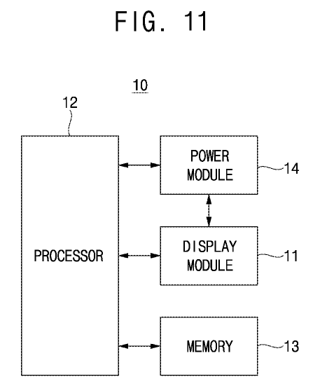

The driving controller CON may receive input image data IMG and an input control signal CONT from an external device (e.g., a processor 12 of FIG. 11). For example, the input image data IMG may include red image data, green image data, and blue image data. For example, the input image data IMG may include white image data. For example, the input image data IMG may include magenta image data, yellow image data, and cyan image data. The input control signal CONT may include a master clock signal and a data enable signal. The input control signal CONT may further include a vertical synchronization signal and a horizontal synchronization signal.

The driving controller CON may generate a first control signal CONT1, a second control signal CONT2, a third control signal CONT3, a fourth control signal CONT4, and a data signal DATA based on the input image data IMG and the input control signal CONT.

The driving controller CON may generate the first control signal CONT1 for controlling the operation of the gate driver GIC based on the input control signal CONT, and may output the first control signal CONT1 to the gate driver GIC. The first control signal CONT1 may include a scan start signal, a gate clock signal, or the like.

The driving controller CON may generate the second control signal CONT2 for controlling the operation of the data driver DIC based on the input control signal CONT, and may output the second control signal CONT2 to the data driver DIC. The second control signal CONT2 may include a horizontal start signal, a load signal, or the like.

The driving controller CON may generate the data signal DATA based on the input image data IMG. The driving controller CON may output the data signal DATA to the data driver DIC.

The driving controller CON may generate the third control signal CONT3 for controlling the operation of the gamma reference voltage generator GRV based on the input control signal CONT, and may output the third control signal CONT3 to the gamma reference voltage generator GRV.

The driving controller CON may generate the fourth control signal CONT4 for controlling the operation of the emission driver ED based on the input control signal CONT, and may output the fourth control signal CONT4 to the emission driver ED.

The gate driver GIC may generate gate signals for driving the gate lines GL in response to the first control signal CONT1 received from the driving controller CON. The gate driver GIC may output the gate signals to the gate lines GL.

The gamma reference voltage generator GRV may generate a gamma reference voltage VGREF in response to the third control signal CONT3 received from the driving controller CON. The gamma reference voltage generator GRV may provide the gamma reference voltage VGREF to the data driver DIC. The gamma reference voltage VGREF may have a value corresponding to each data signal DATA.

For example, the gamma reference voltage generator GRV may be disposed in the driving controller CON or in the data driver DIC.

The data driver DIC may receive the second control signal CONT2 and the data signal DATA from the driving controller CON, and may receive the gamma reference voltage VGREF from the gamma reference voltage generator GRV. The data driver DIC may convert the data signal DATA into a data voltage in analog form using the gamma reference voltage VGREF. The data driver DIC may output the data voltage to the data lines DL.

The emission driver ED may generate emission control signals for driving the emission control lines EML in response to the fourth control signal CONT4 received from the driving controller CON. The emission driver ED may output the emission control signals to the emission control lines EML.

For convenience of description, FIG. 2 illustrates that the gate driver GIC is disposed to be spaced apart from the display panel DP in the direction opposite to the second direction D2, and the emission driver ED is disposed to be spaced apart from the display panel DP in the second direction D2, but aspects of the present disclosure are not limited thereto. For example, both the gate driver GIC and the emission driver ED may be disposed on one side of the display panel DP (e.g., one side spaced apart from the display panel DP in the second direction D2). For example, each of the gate driver GIC and the emission driver ED may be disposed on both sides of the display panel DP. For example, the gate driver GIC and the emission driver ED may be integrally formed.

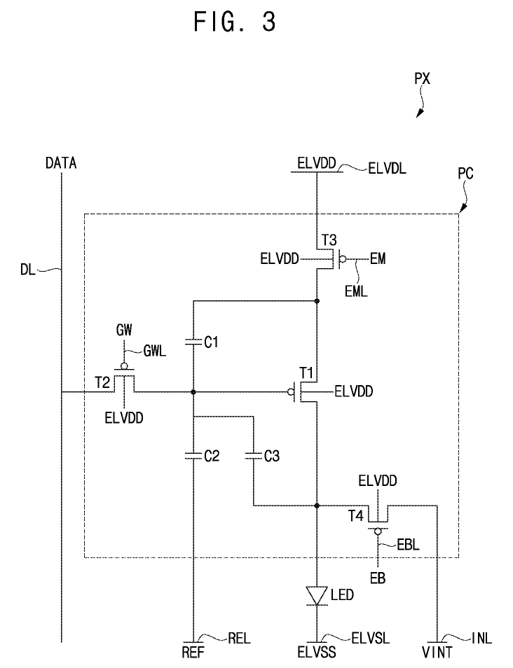

FIG. 3 is an equivalent circuit diagram illustrating an aspect of a pixel of FIG. 2.

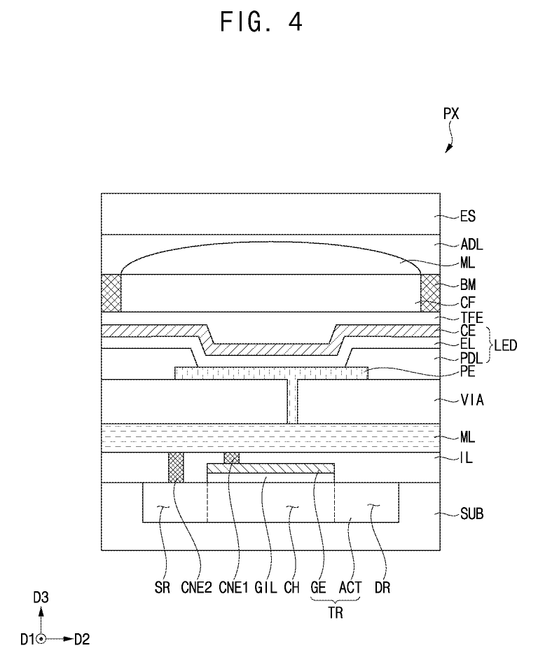

Referring to FIGS. 2 and 3, the pixel PX may include a light emitting element LED and a pixel circuit PC. One of transistors included in the pixel circuit PC of FIG. 3 may correspond to a transistor TR of FIG. 4. The pixel circuit PC may include first to fourth transistors T1, T2, T3, and T4 and first to third capacitors C1, C2, and C3.

In an aspect, each of the first transistor T1, the second transistor T2, the third transistor T3, and the fourth transistor T4 may be metal-oxide-semiconductor field-effect transistor (MOSFET) formed by a semiconductor process.

For example, each of the first transistor T1, the second transistor T2, the third transistor T3, and the fourth transistor T4 may be PMOS transistor. However, the aspects of the present disclosure are not necessarily limited thereto.

The first transistor T1 may include a gate electrode, a first electrode, and a second electrode. The gate electrode of the first transistor T1 may be connected to a second electrode of the second transistor T2. The first electrode of the first transistor T1 may be connected to a second electrode of the third transistor T3. The second electrode of the first transistor T1 may be connected to a second electrode of the fourth transistor T4. The first transistor T1 may provide a driving current to the light emitting element LED. The first transistor T1 may be referred to as a driving transistor.

The first transistor T1 may further include a body electrode. A first power voltage ELVDD may be applied to the body electrode of the first transistor T1. For example, a driving voltage line ELVDL that receives the first power voltage ELVDD may be connected to the body electrode of the first transistor T1. For example, a voltage other than the first power voltage ELVDD may be applied to the body electrode of the first transistor T1.

The second transistor T2 may include a gate electrode, a first electrode, and the second electrode. A first gate signal line GWL that receives a first gate signal GW may be connected to the gate electrode of the second transistor T2. One of the data lines DL that receive a data voltage DATA may be connected to the first electrode of the second transistor T2. The second electrode of the second transistor T2 may be connected to the gate electrode of the first transistor T1. The second transistor T2 may be referred to as a data write transistor.

The second transistor T2 may further include a body electrode. The first power voltage ELVDD may be applied to the body electrode of the second transistor T2. For example, the driving voltage line ELVDL that receives the first power voltage ELVDD may be connected to the body electrode of the second transistor T2. For example, a voltage other than the first power voltage ELVDD may be applied to the body electrode of the second transistor T2.

The second transistor T2 may be turned on or off in response to the first gate signal GW. For example, when the first gate signal GW has an active level, the second transistor T2 may be turned on. In this case, the second transistor T2 may provide the data voltage DATA to the first transistor T1. In contrast, when the first gate signal GW has a non-active level, the second transistor T2 may be turned off. In this case, the second transistor T2 may not provide the data voltage DATA to the first transistor T1.

The third transistor T3 may include a gate electrode, a first electrode, and the second electrode. The gate electrode of the third transistor T3 may be connected to an emission control line EML that receives an emission control signal EM. The first electrode of the third transistor T3 may be connected to the driving voltage line ELVDL that receives the first power voltage ELVDD. The second electrode of the third transistor T3 may be connected to the first electrode of the first transistor T1. The third transistor T3 may be referred to as an emission control transistor.

The third transistor T3 may further include a body electrode. The first power voltage ELVDD may be applied to the body electrode of the third transistor T3. For example, the driving voltage line ELVDL that receives the first power voltage ELVDD may be connected to the body electrode of the third transistor T3. For example, a voltage other than the first power voltage ELVDD may be applied to the body electrode of the third transistor T3.

The third transistor T3 may be turned on or off in response to the emission control signal EM. For example, when the emission control signal EM has an active level, the third transistor T3 may be turned on. In this case, the third transistor T3 may provide the driving current generated by the first transistor T1 to a first electrode of the light emitting element LED. In contrast, when the emission control signal EM has a non-active level, the third transistor T3 may be turned off. In this case, the third transistor T3 may not provide the driving current generated from the first transistor T1 to the first electrode of the light emitting element LED.

The fourth transistor T4 may include a gate electrode, a first electrode, and the second electrode. A second gate signal line EBL that receives a second gate signal EB may be connected to the gate electrode of the fourth transistor T4. An initialization voltage line INL that receives an initialization voltage VINT may be connected to the first electrode of the fourth transistor T4. The second electrode of the fourth transistor T4 may be connected to the second electrode of the first transistor T1. That is, the fourth transistor T4 may be electrically connected to the first transistor T1. The fourth transistor T4 may be referred to as an initialization transistor.

The fourth transistor T4 may further include a body electrode. The first power voltage ELVDD may be applied to the body electrode of the fourth transistor T4. For example, the driving voltage line ELVDL that receives the first power voltage ELVDD may be connected to the body electrode of the fourth transistor T4. For example, a voltage other than the first power voltage ELVDD may be applied to the body electrode of the fourth transistor T4.

The fourth transistor T4 may be turned on or off in response to the second gate signal EB. For example, when the second gate signal EB has an active level, the fourth transistor T4 may be turned on. In this case, the fourth transistor T4 may provide the initialization voltage VINT to the light emitting element LED. In contrast, when the second gate signal EB has a non-active level, the fourth transistor T4 may be turned off. In this case, the fourth transistor T4 may not provide the initialization voltage VINT to the light emitting element LED.

The first capacitor C1 may include a first electrode and a second electrode. The first electrode of the first capacitor C1 may be connected to the second electrode of the third transistor T3. The second electrode of the first capacitor C1 may be connected to the gate electrode of the first transistor T1.

The second capacitor C2 may include a first electrode and a second electrode. A reference voltage line REL that receives a reference voltage REF may be connected to the first electrode of the second capacitor C2. The second electrode of the second capacitor C2 may be connected to the gate electrode of the first transistor T1.

The third capacitor C3 may include a first electrode and a second electrode. The first electrode of the third capacitor C3 may be connected to the second electrode of the fourth transistor T4. The second electrode of the third capacitor C3 may be connected to the gate electrode of the first transistor T1.

The light emitting element LED may include the first electrode and a second electrode. The first electrode of the light emitting element LED may be connected to the second electrode of the fourth transistor T4. A common voltage line ELVSL that receives a second power voltage ELVSS may be connected to the second electrode of the light emitting element LED. The second power voltage ELVSS may have a lower voltage level than the first power voltage ELVDD.

FIG. 3 illustrates that the pixel circuit PC includes four transistors and three capacitors, but aspects of the present disclosure are not necessarily limited thereto. The pixel circuit PC may include three or fewer, or five or more, transistors, and may include two or fewer, or four or more, capacitors.

FIG. 4 is a cross-sectional view illustrating an aspect of a display panel of FIG. 2.

Referring to FIGS. 2-4, the pixel PX may include the display panel DP and an encapsulation substrate ES. The display panel DP may include a substrate SUB, a transistor TR, an insulating layer IL, a first connection electrode CNE1, a second connection electrode CNE2, electrode line layers ML, a via insulating layer VIA, a light emitting element LED, a pixel defining layer PDL, an encapsulation layer TFE, a color filter CF, a light blocking layer BM, and a micro lens MLE that are sequentially stacked.

The transistor TR may include an active pattern ACT and a gate electrode GE. The light emitting element LED may include a pixel electrode PE, an emission layer EL, and a common electrode CE. In an aspect, the transistor TR illustrated in FIG. 4 may correspond to the first transistor T1 illustrated in FIG. 3. The light emitting element LED illustrated in FIG. 4 may correspond to the light emitting element LED illustrated in FIG. 3.

The substrate SUB may include a silicon wafer substrate formed using a semiconductor process. The substrate SUB may support other components of the display device DD. For example, the substrate SUB may include a semiconductor material (e.g., a group IV semiconductor, a group III-V compound semiconductor, a group II-VI compound semiconductor, or the like). However, aspects of the present disclosure are not necessarily limited thereto.

The active pattern ACT may be defined on an upper surface of the substrate SUB. For example, the active pattern ACT may include a source region SR, a drain region DR, and a channel region CH. The active pattern ACT may be formed by doping an N-type material or a P-type material on the upper surface of the substrate SUB. In an aspect, the source region SR may be the first electrode of the first transistor T1, and the drain region DR may be the second electrode of the first transistor T1.

The gate electrode GE may be disposed on the substrate SUB. The gate electrode GE may overlap the channel region CH of the active pattern ACT in a plan view. The gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloys containing aluminum, alloys containing silver, alloys containing copper, alloys containing molybdenum, aluminum nitride (AlNₓ), tungsten nitride (WNₓ), titanium nitride (TiNₓ), chromium nitride (CrNₓ), tantalum nitride (TaNₓ), strontium ruthenium oxide (SrRuOₓ), zinc oxide (ZnOₓ), indium tin oxide (ITO), tin oxide (SnOₓ), indium oxide (InOₓ), gallium oxide (GaOₓ), indium zinc oxide (IZO), or the like. These may be used alone or in combination with each other. However, aspects of the present disclosure are not necessarily limited thereto.

A gate insulating layer GIL may be disposed between the substrate SUB and the gate electrode. The gate insulating layer GIL may include an inorganic insulating material and/or an organic insulating material. FIG. 4 illustrates that the gate insulating layer GIL is only disposed under the gate electrode GE, but aspects of the present disclosure are not limited thereto, and the gate insulating layer GIL may be entirely disposed on the substrate SUB.

The transistor TR illustrated in FIG. 4 may correspond to one of the first to fourth transistors T1, T2, T3, and T4 included in the pixel PX illustrated in FIG. 3.

The insulating layer IL may be disposed on the gate electrode GE. For example, the insulating layer IL may be disposed on the substrate SUB and may cover the gate electrode GE. The insulating layer IL may prevent contact between the electrode line layers ML and the transistor TR. The insulating layer IL may include an organic insulating material and/or an inorganic insulating material. For example, the insulating layer IL may include a plurality of layers formed of various insulating materials.

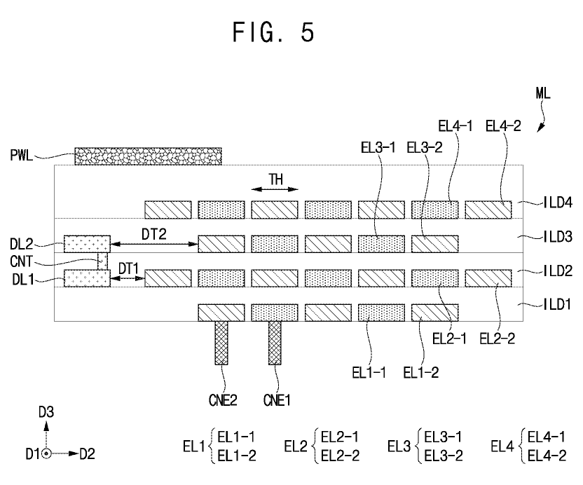

The electrode line layers ML may be disposed on the insulating layer IL. The electrode line layers ML may transmit an electrical signal generated from the transistor TR to the light emitting element LED. The electrode line layers ML may be formed of a plurality of electrode lines and a plurality of interlayer insulating layers. The electrode lines of the electrode line layers ML may form the first to third capacitors C1, C2, and C3 of FIG. 3. The arrangement and shape of the electrode line layers ML will be described later with reference to FIGS. 5-9.

The via insulating layer VIA may be disposed on the electrode line layers ML. The via insulating layer VIA may be referred to as a planarization layer having a flat upper surface. The via insulating layer VIA may include an organic insulating material. That is, the via insulating layer VIA may prevent a short circuit from occurring between the electrode line layers ML and the light emitting element LED. The via insulating layer VIA may be formed only the display region DA and a portion of the peripheral region SA surrounding the display region DA. However, aspects of the present disclosure are not limited thereto.

The pixel electrode PE may be disposed on the via insulating layer VIA. The pixel electrode PE may include a conductive material. The pixel electrode PE may be connected to the source region SR through the electrode line layers ML and the second connection electrode CNE2. Accordingly, the pixel electrode PE may be electrically connected to the transistor TR.

The pixel defining layer PDL may be disposed on the pixel electrode PE. For example, the pixel defining layer PDL may expose at least a portion of the pixel electrode PE. That is, the pixel defining layer PDL may define an opening by exposing at least a portion of the pixel electrode PE. The pixel defining layer PDL may include an inorganic insulating material and/or an organic insulating material.

The emission layer EL may be disposed on the pixel electrode PE. In an aspect, the emission layer EL may be disposed in the opening defined in the pixel defining layer PDL. That is, the emission layer EL may be surrounded by the pixel defining layer PDL. In an aspect, the emission layer EL may also be disposed on the pixel defining layer PDL. The emission layer EL may include an organic light emitting material and/or a quantum dot. However, aspects of the present disclosure are not limited thereto.

The common electrode CE may be disposed on the emission layer EL. The common electrode CE may also be disposed on the pixel defining layer PDL. That is, the common electrode CE may be continuously disposed on the emission layer EL and the pixel defining layer PDL. The common electrode CE may include a conductive material. The emission layer EL may emit light based on a voltage difference between the pixel electrode PE and the common electrode CE.

The encapsulation layer ENC may be disposed on the common electrode CE. The encapsulation layer ENC may include at least one inorganic encapsulation layer and at least one organic encapsulation layer. In an aspect, the inorganic encapsulation layer and the organic encapsulation layer may be alternately disposed. For example, the organic encapsulation layer may include a polymer cured material, such as polyacrylate, epoxy resin, silicone resin, or the like. For example, the inorganic encapsulation layer may include silicon oxide, silicon nitride, silicon carbide, aluminum oxide, tantalum oxide, hafnium oxide, zirconium oxide, titanium oxide, or the like.

The color filter CF may selectively transmit light of a specific wavelength and absorb light of the remaining wavelengths. For example, the color filter CF may transmit red light and absorb light other than the red light. However, aspects of the present disclosure are not limited thereto. The color filter CF may transmit light of colors of red, green, blue, or a combination thereof.

The light blocking layer BM may be disposed on the encapsulation layer TFE. The light blocking layer BM may be disposed between the adjacent color filters CF. The light blocking layer BM may block light incident on the light blocking layer BM. Accordingly, the light blocking layer BM may prevent or reduce color mixing between light emitted from the pixel PX and light emitted from an adjacent pixel. For example, the light blocking layer BM may include an organic material and/or an inorganic material including a black pigment, a black dye, or the like.

The micro lens MLE may be disposed on the color filter CF. The micro lens MLE may improve light extraction efficiency of the pixel PX. The micro lens MLE may overlap the color filter CF in a plan view. The micro lens MLE may have a certain refractive index for visible light. For example, the micro lens MLE may have a refractive index of about 1.5 or more and about 1.7 or less for visible light. For example, the micro lens MLE may have a convex cross-sectional shape. However, aspects of the present disclosure are not necessarily limited thereto.

The encapsulation substrate ES may be disposed on the micro lens MLE. The encapsulation substrate ES may be attached to the display panel DP through an adhesive layer ADL. The encapsulation substrate ES may protect the display panel DP from moisture or gas inflow. The encapsulation substrate ES may include a transparent insulating substrate. For example, the encapsulation substrate ES may include glass. For example, the adhesive layer ADL may include an optical clear adhesive (OCA), a pressure sensitive adhesive (PSA), a photocurable resin, a thermosetting resin, or the like.

FIG. 5 is a cross-sectional view illustrating an aspect of an electrode line layer of FIG. 4.

Referring to FIGS. 4 and 5, the electrode line layers ML may include a first electrode line layer EL1, a second electrode line layer EL2, a third electrode line layer EL3, and a fourth electrode line layer EL4.

For example, the first electrode line layer EL1 may include a first-first electrode line EL1-1 and a first-second electrode line EL1-2. The second electrode line layer EL2 may include a second-first electrode line EL2-1 and a second-second electrode line EL2-2. The third electrode line layer EL3 may include a third-first electrode line EL3-1 and a third-second electrode line EL3-2. The fourth electrode line layer EL4 may include a fourth-first electrode line EL4-1 and a fourth-second electrode line EL4-2.

The first-first electrode line EL1-1 and the first-second electrode line EL1-2 may be disposed in the lowest layer of the electrode line layers ML. The first-first electrode line EL1-1 and the first-second electrode line EL1-2 may be alternately disposed when viewed in the first direction D1 in the cross sectional view. That is, as illustrated in FIG. 5, the first-first electrode line EL1-1 and the first-second electrode line EL1-2 may be alternately disposed in the second direction D2. Each of the first-first electrode line EL1-1 and the first-second electrode line EL1-2 may include a conductive material.

Different voltages may be applied to the first-first electrode line EL1-1 and the first-second electrode line EL1-2. For example, the first-first electrode line EL1-1 and the first-second electrode line EL1-2 may be electrically connected to the first connection electrode CNE1 and the second connection electrode CNE2, respectively. For example, the first-first electrode line EL1-1 may be electrically connected to the first connection electrode CNE1, and the first-second electrode line EL1-2 may be electrically connected to the second connection electrode CNE2.

Accordingly, the first-first electrode line EL1-1 may be electrically connected to the gate electrode GE, and the first-second electrode line EL1-2 may be electrically connected to the source region SR of the active pattern ACT. Since the first-first electrode line EL1-1 shares a voltage with the gate electrode GE and the first-second electrode line EL1-2 shares a voltage with the source region SR, the first-first electrode line EL1-1 and the first-second electrode line EL1-2 may form a capacitor (e.g., the first capacitor C1 of FIG. 3) in the second direction D2.

In an aspect, the first-first electrode line EL1-1, the second-first electrode line EL2-1, the third-first electrode line EL3-1, and the fourth-first electrode line EL4-1 may be electrically connected to each other. That is, the first-first electrode line EL1-1, the second-first electrode line EL2-1, the third-first electrode line EL3-1, and the fourth-first electrode line EL4-1 may share the same voltage.

In an aspect, the first-second electrode line EL1-2, the second-second electrode line EL2-2, the third-second electrode line EL3-2, and the fourth-second electrode line EL4-2 may be electrically connected to each other. That is, the first-second electrode line EL1-2, the second-second electrode line EL2-2, the third-second electrode line EL3-2, and the fourth-second electrode line EL4-2 may share the same voltage.

In an aspect, the first-first electrode line EL1-1 and the first-second electrode line EL1-2 may be spaced apart from each other by about 0.05 micrometers or more and about 0.15 micrometers or less in the second direction D2.For example, the first-first electrode line EL1-1 and the first-second electrode line EL1-2 may be spaced apart from each other by about 0.07 micrometers or more and about 0.13 micrometers or less in the second direction D2. Since the first-first electrode line EL1-1 and the first-second electrode line EL1-2 are spaced apart from each other by the range described above, the first-first electrode line EL1-1 and the first-second electrode line EL1-2 may form the capacitor required for the operation of the display device DD.

A first interlayer insulating layer ILD1 may be disposed on the first electrode line layer EL1. For example, the first interlayer insulating layer ILD1 may be disposed on the insulating layer IL and may cover the first electrode line layer EL1. The first interlayer insulating layer ILD1 may prevent contact between the first electrode line layer EL1 and the second electrode line layer EL2. For example, the first interlayer insulating layer ILD1 may include an oxide (e.g., silicon oxide (SiO₂)).

The second electrode line layer EL2 may be disposed on the first interlayer insulating layer ILD1. The second-first electrode line EL2-1 and the second-second electrode line EL2-2 included in the second electrode line layer EL2 may be alternately disposed in the second direction D2. That is, similar to the first electrode line layer EL1, the second electrode line layer EL2 may form a capacitor in the second direction D2.

In an aspect, the first-first electrode line EL1-1 and the second-second electrode line EL2-2 may at least partially overlap each other in a plan view. The first-second electrode line EL1-2 and the second-first electrode line EL2-1 may at least partially overlap each other in a plan view. Since the first-first electrode line EL1-1 and the second-second electrode line EL2-2 overlap each other in a plan view, and the first-second electrode line EL1-2 and the second-first electrode line EL2-1 overlap each other in a plan view, the first electrode line layer EL1 and the second electrode line layer EL2 may form a capacitor in the third direction D3 in a cross-sectional view.

A first data line DL1 may be disposed on the first interlayer insulating layer ILD1. That is, the first data line DL1 may be disposed on the same layer as the second electrode line layer EL2. The first data line DL1 may be spaced apart from the second electrode line layer EL2 in a plan view. The first data line DL1 may correspond to the data line DL of FIG. 3. The first data line DL1 may apply a data voltage.

In an aspect, the first data line DL1 may be disposed closer to the second-second electrode line EL2-2 than to the second-first electrode line EL2-1. That is, in the second electrode line layer EL2, the second-second electrode line EL2-2 may be disposed further outward than the second-first electrode line EL2-1. Since the second-second electrode line EL2-2 is disposed closer to the first data line DL1 than to the second-first electrode line EL2-1, a coupling between the second-first electrode line EL2-1 and the first data line DL1 may be prevented or reduced. Accordingly, by disposing the second-second electrode line EL2-2 between the second-first electrode line EL2-1 electrically connected to the gate electrode GE and the first data line DL1, a reliability of the voltage of the gate electrode GE driving the transistor TR may be improved.

In an aspect, the second-second electrode line EL2-2 and the first data line DL1 may be spaced apart from each other by a first spacing distance DT1 in the second direction D2. For example, the first spacing distance DT1 may be in a range of about 0.1 micrometers or more and about 0.2 micrometers or less. For example, the first spacing distance DT1 may be in a range of about 0.12 micrometers or more and about 0.18 micrometers or less. Since the first spacing distance DT1 satisfies the range, the coupling between the second electrode line layer EL2 and the first data line DL1 may be prevented or reduced.

A second interlayer insulating layer ILD2 may be disposed on the second electrode line layer EL2 and the first data line DL1. The second interlayer insulating layer ILD2 may prevent contact between the second electrode line layer EL2 and the third electrode line layer EL3. For example, the second interlayer insulating layer ILD2 may include the same material as the first interlayer insulating layer ILD1.

The third electrode line layer EL3 may be disposed on the second interlayer insulating layer ILD2. The third-first electrode line EL3-1 and the third-second electrode line EL3-2 included in the third electrode line layer EL3 may be alternately disposed in the second direction D2. That is, similar to the first electrode line layer EL1, the third electrode line layer EL3 may form a capacitor in the second direction D2.

In an aspect, the second-first electrode line EL2-1 and the third-second electrode line EL3-2 may at least partially overlap each other in a plan view. The second-second electrode line EL2-2 and the third-first electrode line EL3-1 may at least partially overlap each other in a plan view. Since the second-first electrode line EL2-1 and the third-second electrode line EL3-2 overlap each other in a plan view, and the second-second electrode line EL2-2 and the third-first electrode line EL3-1 overlap each other in a plan view, the second electrode line layer EL2 and the third electrode line layer EL3 may form a capacitor in the third direction D3 in a cross-sectional view.

A second data line DL2 may be disposed on the second interlayer insulating layer ILD2. That is, the second data line DL2 may be disposed on the same layer as the third electrode line layer EL3. The second data line DL2 may be spaced apart from the third electrode line layer EL3 in a plan view. The second data line DL2 may correspond to the data line DL of FIG. 3. The second data line DL2 may be electrically connected to the first data line DL1. For example, the second data line DL2 may be electrically connected to the first data line DL1 through a contact electrode CNT penetrating the second interlayer insulating layer ILD2. The second data line DL2 may include the same material as the first data line DL1.

In an aspect, the second data line DL2 may be disposed closer to the third-second electrode line EL3-2 than to the third-first electrode line EL3-1. That is, in the third electrode line layer EL3, the third-second electrode line EL3-2 may be disposed further outward than the third-first electrode line EL3-1. Since the third-second electrode line EL3-2 is disposed closer to the second data line DL2 than the third-first electrode line EL3-1, a coupling between the third-first electrode line EL3-1 and the second data line DL2 may be prevented or reduced. Accordingly, by disposing the third-second electrode line EL3-2 between the third-first electrode line EL3-1 electrically connected to the gate electrode GE and the second data line DL2, the reliability of the voltage of the gate electrode GE driving the transistor TR may be improved.

In an aspect, the third-second electrode line EL3-2 and the second data line DL2 may be spaced apart from each other by a second spacing distance DT2 in the second direction D2. For example, the second spacing distance DT2 may be in a range of about 0.25 micrometers or more and about 0.6 micrometers or less. For example, the second spacing distance DT2 may be in a range of about 0.3 micrometers or more and about 0.55 micrometers or less. Since the second spacing distance DT2 satisfies the range, the coupling between the third electrode line layer EL3 and the second data line DL2 may be prevented or reduced.

A third interlayer insulating layer ILD3 may be disposed on the third electrode line layer EL3 and the second data line DL2. The third interlayer insulating layer ILD3 may prevent contact between the second electrode line layer EL2 and the third electrode line layer EL3. For example, the third interlayer insulating layer ILD3 may include the same material as the first interlayer insulating layer ILD1.

The fourth electrode line layer EL4 may be disposed on the third interlayer insulating layer ILD3. The fourth-first electrode line EL4-1 and the fourth-second electrode line EL4-2 included in the fourth electrode line layer EL4 may be alternately disposed in the second direction D2. That is, similar to the first electrode line layer EL1, the fourth electrode line layer EL4 may form a capacitor in the second direction D2.

In an aspect, the third-first electrode line EL3-1 and the fourth-second electrode line EL4-2 may at least partially overlap each other in a plan view. The third-second electrode line EL3-2 and the fourth-first electrode line EL4-1 may at least partially overlap each other in a plan view. Since the third-first electrode line EL3-1 and the fourth-second electrode line EL4-2 overlap each other in a plan view and the third-second electrode line EL3-2 and the fourth-first electrode line EL4-1 overlap each other in a plan view, the third electrode line layer EL3 and the fourth electrode line layer EL4 may form a capacitor in the third direction D3 in a cross-sectional view.

A fourth interlayer insulating layer ILD4 may be disposed on the fourth electrode line layer EL4. For example, the fourth interlayer insulating layer ILD4 may include the same material as the first interlayer insulating layer ILD1.

A power electrode line PWL may be disposed on the fourth interlayer insulating layer ILD4. The power electrode line PWL may apply a power voltage. For example, the power electrode line PWL may correspond to the driving voltage line ELVDL illustrated in FIG. 3. That is, the power electrode line PWL may apply the first power voltage. In a plan view, a width of the power electrode line PWL may be about in a range of about 6,000 angstroms or more and about 15,000 angstroms or less.

In an aspect, in a plan view, a width TH of each of the first-first to fourth-second electrode lines EL1-1 to EL4-2 included in the electrode line layers ML may be in a range of about 0.1 micrometers or more and about 0.25 micrometers or less. For example, in a plan view, the width TH of each of the first-first to fourth-second electrode lines EL1-1 to EL4-2 included in the electrode line layers ML may be in a range of about 0.12 micrometers or more and about 0.23 micrometers or less. Since the width TH of each of the first-first to fourth-second electrode lines EL1-1 to EL4-2 satisfies the range, a power consumption of each of the first-first to fourth-second electrode lines EL1-1 to EL4-2 may be reduced, and a size of the pixel PX may be reduced.

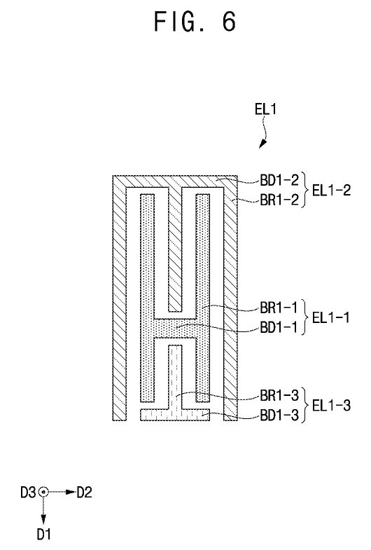

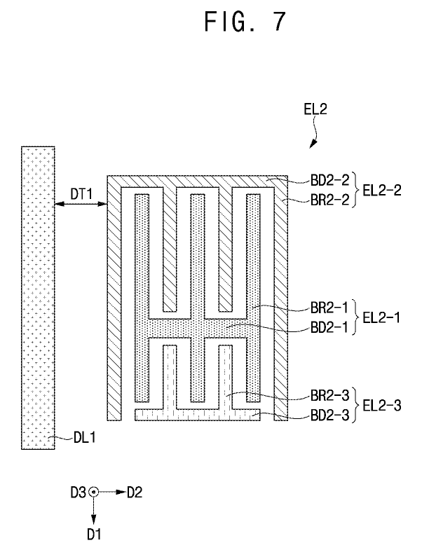

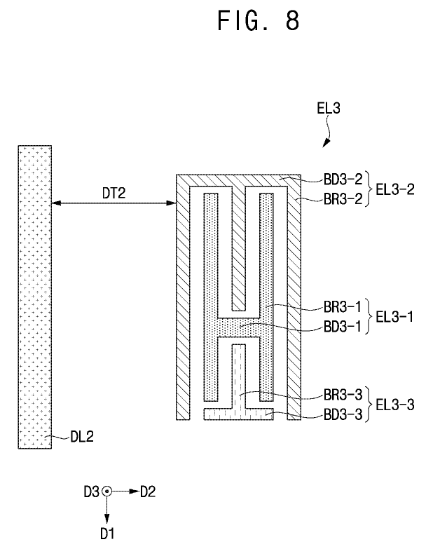

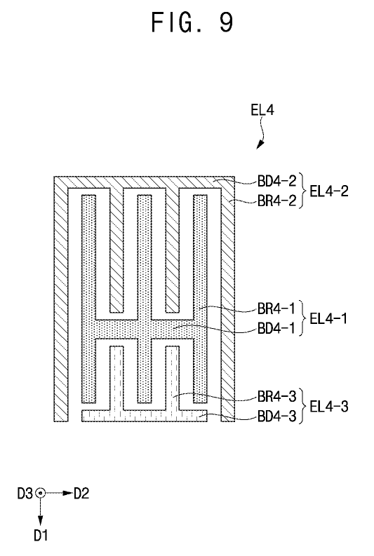

Referring further to FIGS. 6-9, the first electrode line layer EL1 may further include a first-third electrode line (e.g., a first-third electrode line EL1-3 of FIG. 6). The second electrode line layer EL2 may further include a second-third electrode line (e.g., a second-third electrode line EL2-3 of FIG. 7). The third electrode line layer EL3 may further include a third-third electrode line (e.g., a third-third electrode line EL3-3 of FIG. 8). The fourth electrode line layer EL4 may further include a fourth-third electrode line (e.g., a fourth-third electrode line EL4-3 of FIG. 9). The arrangement and shape of the first-third electrode line EL1-3, the second-third electrode line EL2-3, the third-third electrode line EL3-3, and the fourth-third electrode line EL4-3 will be described later with reference to FIGS. 6 and 9.

FIG. 6 is a plan view illustrating an aspect of a first electrode line layer of FIG. 5.

Referring to FIGS. 5 and 6, the first electrode line layer EL1 may further include the first-third electrode line EL1-3 spaced apart from the first-first electrode line EL1-1 and the first-second electrode line EL1-2 in a plan view. That is, the first electrode line layer EL1 may include the first-first electrode line EL1-1, the first-second electrode line EL1-2, and the first-third electrode line EL1-3.

The first-first electrode line EL1-1 may include a first-first body portion BD1-1 extending in the second direction D2 and first-first branch portions BR1-1 each extending from the first-first body portion BD1-1 in the first direction D1 and in a direction opposite to the first direction D1. FIG. 6 illustrates that the first-first electrode line EL1-1 has ‘H’ shape in a plan view, but aspects of the present disclosure are not limited thereto. In an aspect, a number of the first-first branch portions BR1-1 of the first-first electrode line EL1-1 may be three or less or five or more.

The first-second electrode line EL1-2 may include a first-second body portion BD1-2 extending in the second direction D2 and first-second branch portions BR1-2 each extending from the first-second body portion BD1-2 in the first direction D1. Lengths of at least some of the first-second branch portions BR1-2 in the first direction D1 may be different from each other. FIG. 6 illustrates that a number of the first-second branch portions BR1-2 is three, but aspects of the present disclosure are not limited thereto. In an aspect, the number of the first-second branch portions BR1-2 may be two or less or four or more.

The first-third electrode line EL1-3 may include a first-third body portion BD1-3 extending in the second direction D2 and a first-third branch portion BR1-3 extending from the first-third body portion BD1-3 in the direction opposite to the first direction D1. FIG. 6 illustrates that a number of the first-third branch portion BR1-3 is one, but aspects of the present disclosure are not limited thereto. In an aspect, the number of the first-second branch portion BR1-2 may be two or more.

In an aspect, the number of the first-second branch portions BR1-2 may be greater than the number of the first-first branch portions BR1-1.

Since each of the first-first electrode line EL1-1, the first-second electrode line EL1-2, and the first-third electrode line EL1-3 includes a body portion and branch portions, the first electrode line layer EL1 may form the relatively large capacitor per unit area.

In an aspect, the first-first electrode line EL1-1 may be electrically connected to the gate electrode GE of FIG. 4. The first-second electrode line EL1-2 may be electrically connected to the source region SR of FIG. 4. The reference voltage REF of FIG. 3 may be applied to the first-third electrode line EL1-3.

In an aspect, the first-first electrode line EL1-1, the first-second electrode line EL1-2, and the first-third electrode line EL1-3 may be spaced apart from each other in a plan view to form the capacitor. For example, the first-first electrode line EL1-1 and the first-second electrode line EL1-2 may form the first capacitor C1 of FIG. 3. The first-first electrode line EL1-1 and the first-third electrode line EL1-3 may form the second capacitor C2 of FIG. 3.

In an aspect, the first-second electrode line EL1-2 may have a shape that at least partially surrounds the first-first electrode line EL1-1 and the first-third electrode line EL1-3 in a plan view. Since the first-second electrode line EL1-2, which is electrically connected to the source region SR of FIG. 4, receives a constant DC voltage, the first-second electrode line EL1-2 may be less affected by coupling even when the first-second electrode line EL1-2 is disposed closer to the first data line DL1 than the first-first electrode line EL1-1 and the first-third electrode line EL1-3. Accordingly, since the first-second electrode line EL1-2 has a shape that at least partially surrounds the first-first electrode line EL1-1 and the first-third electrode line EL1-3 in a plan view, the coupling between the first electrode line layer EL1 and the first data line DL1 may be prevented or reduced.

FIG. 7 is a plan view illustrating an aspect of a second electrode line layer and a first data line of FIG. 5. For example, descriptions with reference to FIG. 7 may be substantially the same or similar to the descriptions with reference to FIG. 6 except for the first data line DL1. Accordingly, repeated description will be omitted or simplified.

Referring to FIG. 7, The second-first electrode line EL2-1 may include a second-first body portion BD2-1 extending in the second direction D2 and second-first branch portions BR2-1 each extending from the second-first body portion BD2-1 in the first direction D1 and in the direction opposite to the first direction D1. The second-second electrode line EL2-2 may include a second-second body portion BD2-2 extending in the second direction D2 and second-second branch portions BR2-2 each extending from the second-second body portion BD2-2 in the first direction D1. The second-third electrode line EL2-3 may include a second-third body portion BD2-3 extending in the second direction D2 and second-third branch portions BR2-3 each extending from the second-third body portion BD2-3 in the direction opposite to the first direction D1.

Referring to FIGS. 6 and 7, In an aspect, a number of the second-first branch portions BR2-1 may be greater than the number of the first-first branch portions BR1-1, a number of the second-second branch portions BR2-2 may be greater than the number of the first-second branch portions BR1-2, and a number of the second-third branch portions BR2-3 may be greater than the number of the first-third branch portions BR1-3. That is, as illustrated in FIG. 5, the number of branch portions included in the second electrode line layer EL2 may be greater than the number of branch portions included in the first electrode line layer EL1.

In an aspect, the second-first electrode line EL2-1 may be electrically connected to the source region SR of FIG. 4. The second-second electrode line EL2-2 may be electrically connected to the gate electrode GE of FIG. 4. The reference voltage REF of FIG. 3 may be applied to the second-third electrode line EL2-3.

In an aspect, the second-first electrode line EL2-1, the second-second electrode line EL2-2, and the second-third electrode line EL2-3 may be spaced apart from each other in a plan view to form the capacitors. For example, the second-first electrode line EL2-1 and the second-second electrode line EL2-2 may form the first capacitor C1 of FIG. 3. The second-first electrode line EL2-1 and the second-third electrode line EL2-3 may form the second capacitor C2 of FIG. 3.

The first-first branch portions BR1-1 may at least partially overlap the second-second branch portions BR2-2 in a plan view, and the first-second branch portions BR1-2 may at least partially overlap the second-first branch portions BR2-1 in a plan view. The first-first branch portions BR1-1 and the second-second branch portions BR2-2 overlapping each other, and the first-second branch portions BR1-2 and the second-first branch portions BR2-1 overlapping each other may form the first capacitor C1 of FIG. 3.

In an aspect, the first-third branch portion BR1-3 may at least partially overlap one of the second-first branch portions BR2-1. The first-third branch portion BR1-3 and the second-first branch portion BR2-1 overlapping each other may form the second capacitor C2 of FIG. 3.

FIG. 8 is a plan view illustrating an aspect of a third electrode line layer and a second data line of FIG. 5. For example, descriptions with reference to FIG. 8 may be substantially the same or similar to the descriptions with reference to FIG. 6 except for the second data line DL2. Accordingly, repeated description will be omitted or simplified.

Referring to FIG. 8, The third-first electrode line EL3-1 may include a third-first body portion BD3-1 extending in the second direction D2 and third-first branch portions BR3-1 each extending from the third-first body portion BD3-1 in the second direction D1 and in the direction opposite to the second direction D1. The third-second electrode line EL3-2 may include a third-second body portion BD3-2 extending in the second direction D2 and third-second branch portions BR3-2 each extending from the third-second body portion BD3-2 in the second direction D1. The third-third electrode line EL3-3 may include a third-third body portion BD3-3 extending in the second direction D2 and a third-third branch portion BR3-3 extending from the third-third body portion BD3-3 in the direction opposite to the second direction D1.

In an aspect, the third-first electrode line EL3-1 may be electrically connected to the gate electrode GE of FIG. 4. The third-second electrode line EL3-2 may be electrically connected to the source region SR of FIG. 4. The reference voltage REF of FIG. 3 may be applied to the third-third electrode line EL3-3.

In an aspect, the third-first electrode line EL3-1, the third-second electrode line EL3-2, and the third-third electrode line EL3-3 may be spaced apart from each other in a plan view to form the capacitors. For example, the third-first electrode line EL3-1 and the third-second electrode line EL3-2 may form the second capacitor C1 of FIG. 3. The third-first electrode line EL3-1 and the third-third electrode line EL3-3 may form the second capacitor C2 of FIG. 3.

Referring to FIGS. 7 and 8, the second-first branch portions BR2-1 may at least partially overlap the third-second branch portions BR3-2 in a plan view, and the second-second branch portions BR2-2 may at least partially overlap the third-first branch portions BR3-1 in a plan view. The second-first branch portions BR2-1 and the third-second branch portions BR3-2 overlapping each other, and the second-second branch portions BR2-2 and the third-first branch portions BR3-1 overlapping each other may form the second capacitor C1 of FIG. 3.

In an aspect, the second-third branch portions BR2-3 may at least partially overlap the third-first branch portions BR3-1. The second-third branch portions BR2-3 and the third-first branch portions BR3-1 overlapping each other may form the second capacitor C2 of FIG. 3.

FIG. 9 is a plan view illustrating an aspect of a fourth electrode line layer of FIG. 5. For example, descriptions with reference to FIG. 8 may be substantially the same or similar to the descriptions with reference to FIG. 6 except for the number of the branch portions of each of the electrode lines. Accordingly, repeated description will be omitted or simplified.

Referring to FIG. 9, The fourth-first electrode line EL4-1 may include a fourth-first body portion BD4-1 extending in the second direction D2 and fourth-first branch portions BR4-1 each extending from the fourth-first body portion BD4-1 in the second direction D1 and in the direction opposite to the second direction D1. The fourth-second electrode line EL4-2 may include a fourth-second body portion BD4-2 extending in the second direction D2 and fourth-second branch portions BR4-2 each extending from the fourth-second body portion BD4-2 in the second direction D1. The fourth-third electrode line EL4-3 may include a fourth-third body portion BD4-3 extending in the second direction D2 and fourth-third branch portions BR4-3 each extending from the fourth-third body portion BD4-3 in the direction opposite to the second direction D1.

In an aspect, the fourth-first electrode line EL4-1 may be electrically connected to the source region SR of FIG. 4. The fourth-second electrode line EL4-2 may be electrically connected to the gate electrode GE of FIG. 4. The reference voltage REF of FIG. 3 may be applied to the fourth-third electrode line EL4-3.

In an aspect, the fourth-first electrode line EL4-1, the fourth-second electrode line EL4-2, and the fourth-third electrode line EL4-3 may be spaced apart from each other in a plan view to form the capacitors. For example, the fourth-first electrode line EL4-1 and the fourth-second electrode line EL4-2 may form the second capacitor C1 of FIG. 3. The fourth-first electrode line EL4-1 and the fourth-third electrode line EL4-3 may form the second capacitor C2 of FIG. 3.

Referring to FIGS. 8 and 9, the third-first branch portions BR3-1 may at least partially overlap the fourth-second branch portions BR4-2 in a plan view, and the third-second branch portions BR3-2 may at least partially overlap the fourth-first branch portions BR4-1 in a plan view. The third-first branch portions BR3-1 and the fourth-second branch portions BR4-2 overlapping each other, and the third-second branch portions BR3-2 and the fourth-first branch portions BR4-1 overlapping each other may form the second capacitor C1 of FIG. 3.

In an aspect, the third-third branch portion BR3-3 may at least partially overlap one of the fourth-first branch portions BR4-1. The third-third branch portion BR3-3 and the fourth-first branch portion BR4-1 overlapping each other may form the second capacitor C2 of FIG. 3.

As illustrated in FIGS. 1-9, since the first-first electrode line EL1-1 and the second-second electrode line EL2-2, to which different voltages are applied, are disposed to overlap each other in a plan view, the capacitor may also be formed in the third direction D3. Accordingly, compared to a case in which electrode lines, to which the same voltage is applied, are disposed to overlap each other in a plan view, a total capacitance of the capacitor in the display device DD may increase. For example, compared to the case in which electrode lines, to which the same voltage is applied, are disposed to overlap each other in a plan view, the total capacitance of the capacitor in the display device DD may increase by about 0.19 Ff/um².

In addition, since the second-second electrode line EL2-2 electrically connected to the source region SR is disposed closer to the first data line DL1, the coupling between the second-first electrode line EL2-1 and the first data line DL1 may be prevented or reduced. Therefore, the reliability of the display device DD may be improved, and high-resolution images may be stable implemented due to the increased capacitance of the capacitor.

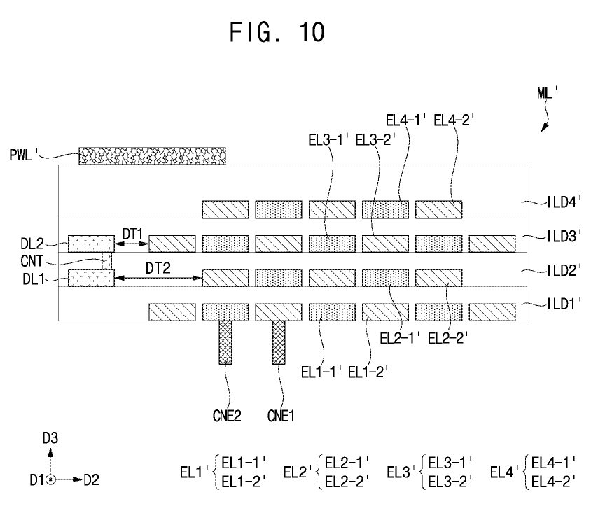

FIG. 10 is a cross-sectional view illustrating an aspect of an electrode line layer of FIG. 4. For example, descriptions with reference to FIG. 9 may be substantially the same or similar to the descriptions with reference to FIG. 5 except for the arrangement of the electrode lines. Accordingly, repeated description will be omitted or simplified.

Referring to FIGS. 4, 5, and 10, the electrode line layers ML’ may include the first electrode line layer EL1’, the second electrode line layer EL2’, the third electrode line layer EL3’, and the fourth electrode line layer EL4’. In addition, in FIG. 5, the number of the branch portions included in the first electrode line layer EL1 is less than the number of the branch portions included in the second electrode line layer EL2, but in FIG. 10, the number of the branch portions included in the first electrode line layer EL1’ may be greater than the number of the branch portions included in the second electrode line layer EL2’.

In an aspect, the second-second electrode line EL2-2’ of the second electrode line layer EL2’ may be spaced apart from the first data line DL1 in the second direction D2 by the second spacing distance DT2. The third-second electrode line EL3-2’ of the third electrode line layer EL3’ may be spaced apart from the second data line DL2’ in the second direction D2 by the first spacing distance DT1.

FIG. 11 is a block diagram illustrating an electronic device according to an aspect.

Referring to FIGS. 1 and 11, the display device DD according to aspects may be applied to various electronic devices 10. The electronic device 10 according to an aspect may include the display device DD described above, and may further include modules or devices with additional functions other than the display device DD.

The electronic device 10 may include a display module 11, a processor 12, a memory 13, and a power module 14.

The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information necessary for the operation of the processor 12 or the display module 11. When the processor 12 executes the application stored in the memory 13, the input image data IMG and/or the input control signal CONT of FIG. 2 may be transmitted to the display module 11, and the display module 11 may process the received signal and output image information through a display screen.

The power module 14 may include a power supply module, such as a power adapter or a battery device, and a power conversion module which converts the power supplied by the power supply module to generate power required for the operation of the electronic device 10.

At least one of each component of the electronic device 10 described above may be included in the display device according to aspects. In addition, some of the individual modules functionally included in one module may be included in the display device, and other portions may be provided separately from the display device. For example, the display device DD may include the display module 11, and the processor 12, the memory 13, and the power module 14 may be provided in the form of other devices within the electronic device 10 other than the display device DD.

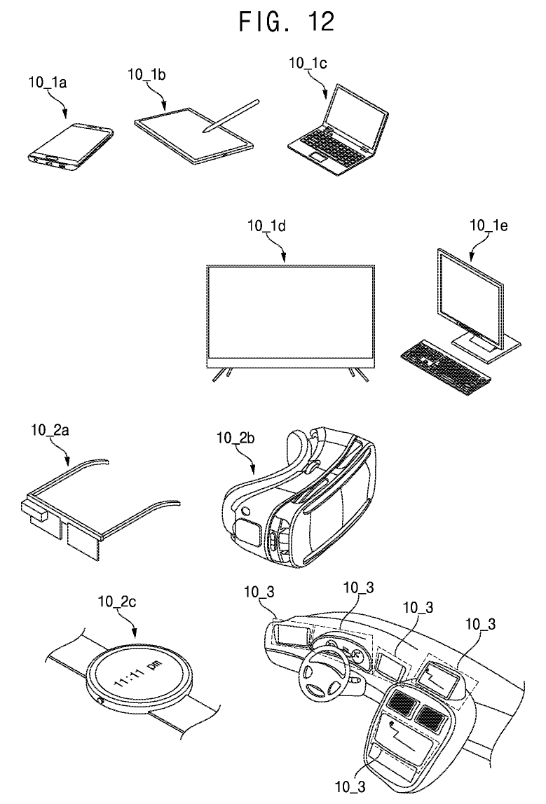

FIG. 12 is a schematic diagram illustrating electronic devices according to various aspects.

Referring to FIGS. 11 and 12, various electronic devices 10 to which the display device DD according to aspects are applied may include not only image display electronic devices such as a smartphone 10_1a, a tablet PC 10_1b, a laptop 10_1c, a TV 10_1d, or a desktop monitor 10_1e, but also wearable electronic devices including display modules, such as smart glasses 10_2a, a head-mounted display 10_2b, or a smart watch 10_2c, automotive electronic devices 10_3 including display modules, such as a dashboard of a car, a center fascia, a Center Information Display “CID” disposed on a dashboard, or a room mirror display, or the like.

Although aspects and implementations have been described herein, other aspects and modifications will be apparent from this description. Accordingly, the present disclosure is not limited to such aspects, but rather to the broader scope of the appended claims and various obvious modifications and equivalent arrangements as would be apparent to a person of ordinary skill in the art.

What is claimed is:

1. A display device comprising:
a substrate;
an active pattern disposed on the substrate, the active pattern comprising a source region, a drain region, and a channel region;
a gate electrode disposed on the active pattern, the gate electrode overlapping the channel region of the active pattern;
a first-first electrode line disposed on the gate electrode in a first electrode line layer, wherein the first-first electrode line is electrically connected to the gate electrode;
a first-second electrode line disposed in the first electrode line layer, wherein the first-second electrode line is electrically connected to the source region of the active pattern, and wherein the first-second electrode line is spaced apart from the first-first electrode line in a plan view;
a first data line disposed on the first-first electrode line in a second electrode line layer, the first data line configured to apply a data voltage;
a second-first electrode line disposed in the second electrode line layer, wherein the second-first electrode line at least partially overlaps the first-second electrode line in the plan view, and wherein the second-first electrode line is electrically connected to the first-first electrode line; and
a second-second electrode line disposed in the second electrode line layer, wherein the second-second electrode line at least partially overlaps the first-first electrode line in the plan view, wherein the second-second electrode line is electrically connected to the first-second electrode line, and wherein the second-second electrode line is closer to the first data line than the second-first electrode line.

2. The display device of claim 1, wherein
the first-first electrode line includes a first-first body portion extending in the first direction and first-first branch portions each extending from the first-first body portion in a second direction, wherein the second direction crosses the first direction,
the first-second electrode line includes a first-second body portion extending in the first direction and first-second branch portions each extending from the first-second body portion in the second direction,
the second-first electrode line includes a second-first body portion extending in the first direction and second-first branch portions each extending from the second-first body portion in the second direction, and
the second-second electrode line includes a second-second body portion extending in the first direction and second-second branch portions each extending from the second-second body portion in the second direction.

3. The display device of claim 2, wherein
the first-first branch portions at least partially overlap the second-second branch portions in the plan view, and
the first-second branch portions at least partially overlap the second-first branch portions in the plan view.

4. The display device of claim 2, wherein
a number of the first-second branch portions of the first-second electrode line is greater than a number of the first-first branch portions of the first-first electrode line, and
a number of the second-second branch portions of the second-second electrode line is greater than a number of the second-first branch portions of the second-first electrode line.

5. The display device of claim 2, wherein a number of the second-first branch portions is greater than a number of the first-first branch portions.

6. The display device of claim 5, wherein
the first data line and the second-second electrode line are spaced apart from each other in the plan view by a first spacing distance, and
the first spacing distance is from about 0.1 micrometers to about 0.2 micrometers.

7. The display device of claim 5, further comprising:
a second data line disposed on the first data line in a third electrode line layer, the second data line electrically connected to the first data line.

8. The display device of claim 7, further comprising:
a third-first electrode line disposed in the third electrode line layer, wherein the third-first electrode line at least partially overlaps the first-first electrode line in the plan view, and wherein the third-first electrode line is electrically connected to the first-first electrode line; and
a third-second electrode line disposed in the third electrode line layer, wherein the third-second electrode line at least partially overlaps the first-second electrode line in the plan view, and wherein the third-second electrode line is electrically connected to the first-second electrode line.

9. The display device of claim 8, wherein
the second data line and the third-second electrode line are spaced apart from each other in the plan view by a second spacing distance, and
the second spacing distance is from about 0.25 micrometers to about 0.6 micrometers.

10. The display device of claim 8, further comprising:
power electrode lines disposed on the third-first electrode line and to which a power voltage is applied.

11. The display device of claim 10, wherein, a width of each of the power electrode lines in a plan view is from about 6000 angstroms to about 15000 angstroms.

12. The display device of claim 7, wherein
a number of the first-second branch portions of the first-second electrode line is greater than a number of the first-first branch portions of the first-first electrode line, and
a number of the second-second branch portions of the second-second electrode line is greater than a number of the second-first branch portions of the second-first electrode line.

13. The display device of claim 12, further comprising:
a third-first electrode line disposed in the third electrode line layer, wherein the third-first electrode line at least partially overlaps the first-first electrode line in the plan view, and wherein the third-first electrode line is electrically connected to the first-first electrode line; and
a third-second electrode line disposed in the third electrode line layer, wherein the third-second electrode line at least partially overlaps the first-second electrode line in the plan view, and wherein the third-second electrode line is electrically connected to the first-second electrode line.

14. The display device of claim 1, further comprising:
a first connection electrode between the gate electrode and the first-first electrode line in a cross-sectional view,
wherein the first connection electrode is electrically connected to the gate electrode and wherein the first connection electrode is electrically connected to the first-first electrode line.

15. The display device of claim 1, further comprising:
a second connection electrode between the active pattern and the first-second electrode line in a cross-sectional view,
wherein the second connection electrode is electrically connected to the active pattern and wherein the second connection electrode is electrically connected to the first-second electrode line.

16. The display device of claim 1, wherein, a width of each of the first-first electrode line and the first-second electrode line in the plan view is from about 0.1 micrometers to about 0.25 micrometers.

17. The display device of claim 1, further comprising:
a first-third electrode line disposed in the first electrode line layer, wherein the first-third electrode line is spaced apart from the first-first electrode line in the plan view, and wherein the first-third electrode line is configures such that a reference voltage is applied to the first-third electrode line.

18. The display device of claim 1, further comprising:
an interlayer insulating layer disposed between the first-first electrode line and the second-first electrode line,
wherein the interlayer insulating layer includes an oxide.

19. An electronic device comprising:
a display device including:
a substrate
an active pattern disposed on the substrate, the active pattern comprising a source region, a drain region, and a channel region;
a gate electrode disposed on the active pattern, the gate electrode overlapping the channel region of the active pattern;
a first-first electrode line disposed on the gate electrode in a first electrode line layer, wherein the first-first electrode line is electrically connected to the gate electrode;
a first-second electrode line disposed in the first electrode line layer, wherein the first-second electrode line is electrically connected to the source region of the active pattern, and wherein the first-second electrode line is spaced apart from the first-first electrode line in a plan view;
a first data line disposed on the first-first electrode line in a second electrode line layer, the first data line configured to apply a data voltage;
a second-first electrode line disposed in the second electrode line layer, wherein the second-first electrode line at least partially overlaps the first-second electrode line in the plan view, and wherein the second-first electrode line is electrically connected to the first-first electrode line; and
a second-second electrode line disposed in the second electrode line layer, wherein the second-second electrode line at least partially overlaps the first-first electrode line in the plan view, wherein the second-second electrode line is electrically connected to the first-second electrode line, and wherein the second-second electrode line is closer to the first data line than the second-first electrode line; and
a processor configured to drive the display device.

20. The electronic device of claim 19, wherein
the first-first electrode line includes a first-first body portion extending in the first direction and first-first branch portions each extending from the first-first body portion in a second direction, wherein the second direction crosses the first direction,
the first-second electrode line includes a first-second body portion extending in the first direction and first-second branch portions each extending from the first-second body portion in the second direction,
the second-first electrode line includes a second-first body portion extending in the first direction and second-first branch portions each extending from the second-first body portion in the second direction, and
the second-second electrode line includes a second-second body portion extending in the first direction and second-second branch portions each extending from the second-second body portion in the second direction.
